(19) United States
(12) Patent Application Publication
(10) Pub. No.: US 2020/0111844 A1
(43) Pub. Date: Apr. 9, 2020

(54) DISPLAY PANEL, METHOD FOR FABRICATING THE SAME, AND DISPLAY DEVICE

(71) Applicants: HEFEI XINSHENG OPTOELECTRONICS TECHNOLOGY CO., LTD., Anhui (CN); BOE TECHNOLOGY GROUP CO., LTD., Beijing (CN)

(72) Inventors: Yangkun JING, Beijing (CN); Li SUN, Beijing (CN); Chinlung LIAO, Beijing (CN)

(21) Appl. No.: 16/451,189

(22) Filed: Jun. 25, 2019

(30) Foreign Application Priority Data
Oct. 9, 2018 (CN) 201811174914.4

(51) Int. Cl. H01L 27/32; H01L 51/56; G06F 3/041

(52) U.S. Cl. CPC H01L 27/323; H01L 27/3246; G06F 2203/04103; G06F 3/0412; H01L 2227/323; H01L 51/56

(57) ABSTRACT

A display panel, a method for fabricating the same, and a display device. The display panel includes: a light emitting device layer comprising a plurality of light emitting devices, wherein each of the plurality of light emitting devices includes a first electrode, a light emitting functional portion and a second electrode which are stacked in this order; and a touch structure layer on a side of the light emitting device layer facing the second electrode, wherein the touch structure layer includes a plurality of third electrodes. At least one of the plurality of third electrodes is electrically connected to at least one second electrode.

### RELATED APPLICATION

The present application claims the benefit of Chinese Patent Application No. 201811174914.4, filed on Oct. 9, 2018, the entire disclosure of which is incorporated herein by reference.

### TECHNICAL FIELD

The present disclosure relates to the field of display technologies, in particular to a display panel, a method for fabricating the same, and a display device.

### BACKGROUND

An OLED (organic light-emitting diode) display device has the advantages of self-luminescence, fast response, wide viewing angle, high brightness, vivid color, thinness, low weight and the like with respect to the liquid crystal display device, and is considered to be a next-generation display technology. Depending on the direction of illumination, the self-luminous elements, i.e., the OLED devices, in the OLED display device may be classified into two types, which are a bottom emission type (also referred to as a bottom illumination type, that is, emitting light in a direction towards a substrate) and a top emission type (also referred to as a top illumination type, that is, emitting light in a direction away from the substrate).

### SUMMARY

According to an exemplary embodiment of the disclosure, a display panel is provided. The display panel comprises:

a light emitting device layer comprising a plurality of light emitting devices, wherein each of the plurality of light emitting devices comprises a first electrode, a light emitting functional portion and a second electrode which are stacked in this order; and

a touch structure layer on a side of the light emitting device layer facing the second electrode, wherein the touch structure layer comprises a plurality of third electrodes, where at least one of the plurality of third electrodes is electrically connected to at least one second electrode.

In some embodiments, the third electrodes are made from at least one selected from the group of graphene, indium tin oxide, indium zinc oxide, and fluorine-doped tin dioxide.

In some embodiments, the touch structure layer further comprises a first insulating layer on a side of the plurality of third electrodes away from the light emitting device layer.

In some embodiments, the first insulating layer is made from at least one selected from the group of polytetrafluoroethylene, fluoro polyethylene, and polyimide.

In some embodiments, the touch structure layer further comprises a plurality of fourth electrodes on a side of the first insulating layer away from the plurality of third electrodes.

In some embodiments, the fourth electrodes are opaque or translucent.

In some embodiments, the fourth electrodes are made from a graphene electrode material or a nano-silver doped graphene electrode material.

In some embodiments, the touch structure layer further comprises a plurality of second insulating blocks on a side of the first insulating layer away from the third electrodes, and at least one fourth electrode is provided between each of the plurality of the second insulating blocks and the first insulating layer.

In some embodiments, second electrodes of the light emitting device layers are connected together to form an entire layer of electrodes, and the third electrodes are electrically connected to the entire layer of electrodes.

In some embodiments, the display panel further comprises a substrate on a side of the light emitting device layer away from the touch structure layer.

In some embodiments, the display panel further comprises a transparent cover plate on a side of the touch structure layer away from the light emitting device layer.

In some embodiments, the display panel further comprises a pixel defining layer between the light emitting device layer and the substrate, where the pixel defining layer is provided with openings, a respective one of the openings is in correspondence with a respective one of the first electrodes, and the openings are arranged in an array.

In some embodiments, the touch structure layer further comprises a plurality of color filter blocks between two adjacent fourth electrodes, and an orthographic projection of each of the plurality of color filter blocks on the substrate overlaps with an orthographic projection of each of the openings on the substrate.

In some embodiments, the display panel further comprises a plurality of post spacers on a side of the pixel defining layer away from the substrate.

In some embodiments, light emitting functional portions of the light emitting devices are connected together to form an entire layer of light emitting functional portion, and the entire layer of light emitting functional portion covers the pixel defining layer and the post spacers.

In some embodiments, an orthographic projection of each of the third electrodes on the substrate overlaps with an orthographic projection of each of the post spacers on the substrate.

In some embodiments, light emitting functional portions of the light emitting devices emit light from a side facing the touch structure layer.

According to another exemplary embodiment of the disclosure, a display device is provided. The display device comprises the display panel descried above.

According to further exemplary embodiment of the disclosure, a method for fabricating a display panel is provided. The method comprising:

forming a light emitting device layer comprising a plurality of light emitting devices, wherein each of the plurality of light emitting devices comprises a first electrode, a light emitting functional portion, and a second electrode which are stacked in this order;

forming a touch structure layer on a side of the light emitting device layer facing the second electrode, wherein the touch structure layer comprising a plurality of third electrodes; and

assembling the light emitting device layer with the touch structure layer,

wherein at least one of the plurality of third electrodes is electrically connected to at least one second electrode.

In some embodiments, forming the touch structure layer comprises:

forming a first insulating layer;

forming the third electrodes on one side of the first insulating layer using by printing;

forming a fourth electrode on the other side of the first insulating layer using by printing.

### BRIEF DESCRIPTION OF THE DRAWINGS

In order to more clearly illustrate the technical solutions in embodiments of the disclosure or related art, the appended drawings needed to be used in the description of the embodiments or the related art will be briefly introduced below. Obviously, the drawings in the following description are only some embodiments of the disclosure, and for those of skilled in the art, other drawings may be obtained according to these drawings without creative work.

FIG. 1 is a schematic cross-sectional view of a display panel according to an embodiment of the present disclosure;

FIG. 2A is a schematic top view of a plurality of third electrodes in a display panel according to an embodiment of the present disclosure;

FIG. 2B is another schematic top view of a plurality of third electrodes in a display panel according to an embodiment of the present disclosure;

FIG. 3 is a schematic cross-sectional view of another display panel according to an embodiment of the present disclosure;

FIG. 4A is a schematic diagram of an arrangement manner of the third electrodes and the fourth electrodes in a display panel according to an embodiment of the present disclosure;

FIG. 4B is a schematic diagram of another arrangement manner of the third electrodes and the fourth electrodes in a display panel according to an embodiment of the present disclosure;

FIG. 4C is a schematic diagram of yet another arrangement manner of the third electrodes and the fourth electrodes in a display panel according to an embodiment of the present disclosure;

FIG. 5A is a partial schematic top view of a display panel according to an embodiment of the present disclosure;

FIG. 5B is a schematic cross-sectional view taken along line AA of FIG. 5A;

FIG. 6 is a schematic cross-sectional view of yet another display panel according to an embodiment of the present disclosure; and

FIG. 7 is a schematic diagram of a blending apparatus involved in a method for fabricating a display panel according to an embodiment of the present disclosure.

### DETAILED DESCRIPTION OF THE EMBODIMENTS

In the following, the technical solutions in the embodiments of the disclosure will be clearly and completely described in connection with the drawings in the embodiments of the disclosure. Obviously, the described embodiments are only part of the embodiments of the disclosure, rather than all embodiments. Based on the embodiments in the disclosure, all other embodiments obtained by those of skilled in the art without creative efforts are all within the protection scope of the disclosure.

In the following, the terms “first” and “second” are used for descriptive purposes only, and are not to be construed as indicating or implying a relative importance or implicitly indicating the number of technical features indicated. Thus, features defined by “first” and “second” may comprise one or more of the features either explicitly or implicitly. In the description of the embodiments of the present application, “a plurality of” refers to two or more, unless otherwise stated.

In the conventional art, an OLED device generally adopts the bottom emission type in which light emitted from a light-emitting portion is emitted from an anode side below, and light is not emitted from a cathode side above the light-emitting portion. Therefore, the thickness of the cathode is not required to be relatively thin. There is no problem that the cathode resistance is too large due to the cathode thickness being too small, which would result in a voltage drop (IR Drop, that is, a potential difference across the resistor).

However, since the aperture ratio of an OLED display device having a bottom emission type OLED device is limited by an opaque structure such as a TFT (thin film transistor), it is difficult for a bottom emission type OLED display device to realize a high-resolution display requirement. Therefore, an OLED display device having a top emission type OLED device is concerned. However, since the light of the top emission type OLED device is required to be emitted from the cathode side, the thickness of the cathode is required to be relatively thin, resulting in too large cathode resistance and a voltage drop therewith.

In addition, in the Integrated-touch-driver (ITD) technology, since a touch element is also required in the OLED display device, the realization of ultra-thin ITD display device is limited.

In view of this, in order to solve the problems of the related art, embodiments of the present disclosure provide a display panel, a method for fabricating the same, and a display device, which may help improve the electrode voltage drop problem of the light emitting device, and meanwhile contribute to the realization of ultra-thin ITD display panel.

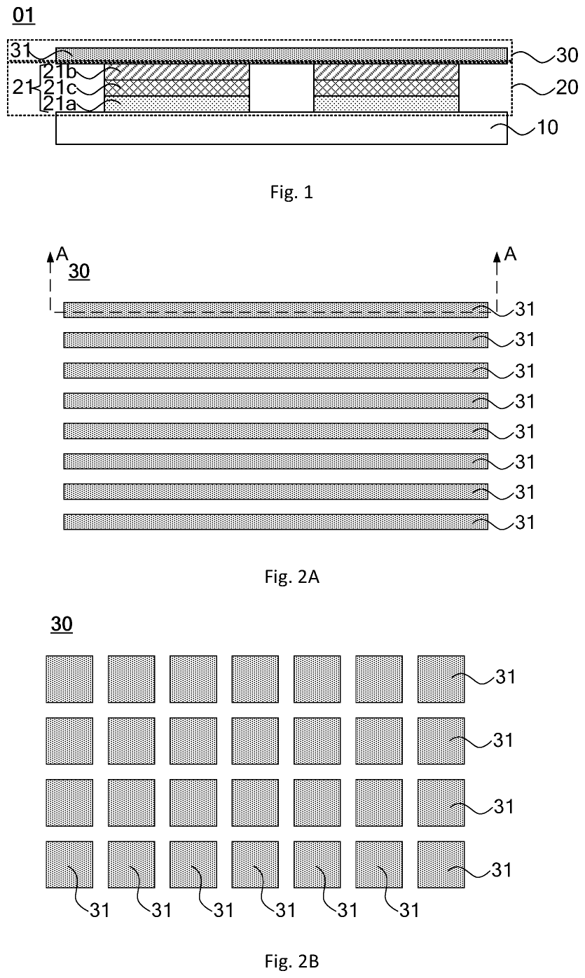

FIG. 1 is a schematic cross-sectional view of a display panel 01 according to an embodiment of the present disclosure. As shown in FIG. 1, the display panel 01 may comprise: a substrate 10; a light emitting device layer 20 above the substrate 10; and a touch structure layer 30 on a side of the light emitting device layer 20 away from the substrate 10. The light emitting device layer 20 comprises a plurality of light emitting devices 21. Each light emitting device 21 comprises a first electrode 21a, a light emitting functional portion 21c, and a second electrode 21b which are disposed in this order away from the substrate 10. The touch structure layer 30 comprises a plurality of third electrodes 31. At least one of the plurality of third electrodes 31 is electrically connected to at least one of the plurality of second electrodes 21b.

It should be noted that, the above-described light-emitting functional portion 21c may specifically comprise functional layers such as an electron transport layer, a light-emitting layer, and a hole transport layer. The first electrode 21a and the second electrode 21b are an anode and a cathode respectively. That is, when the first electrode 21a is an anode, the second electrode 21b is a cathode. Otherwise, when the first electrode 21a is a cathode, the second electrode 21b is an anode.

Here, generally, the above-described display panel may further comprise a thin film transistor array structure layer (i.e., a structural layer composed of a plurality of TFTs) under the light emitting device layer 20, and the anode is generally in electrical communication with the drain (or source) of the TFT to receive the corresponding electrical signals. Therefore, in an embodiment of the present disclosure, the lower first electrode 21a is an anode, and correspondingly, the upper second electrode 21b is a cathode.

Thus, since at least one third electrode 31 is electrically connected to the second electrode 21b, the two are electrically connected to form a parallel structure equivalently, and an equivalent resistance of the second electrode 21b may be reduced.

When the above-described light emitting device 21 is exemplified as a top emission type OLED device, the third electrode 31 may serve as an auxiliary cathode, reducing the equivalent resistance of the second electrode 21b (i.e., the cathode), so that the second electrode 21b may be further thinner and the light extraction rate of the top emission type OLED device may be improved.

Here, the above-described expression “at least one of the plurality of third electrodes 31 is electrically connected to at least one of the plurality of second electrodes 21b″ may refer to at least one third electrode 31 being electrically connected to at least one second electrode 21b, or at least one third electrode 31 being electrically connected to a plurality of second electrodes 21b, or alternatively, a plurality of third electrodes 31 being electrically connected to the plurality of second electrodes 21b. Embodiments of the present disclosure are not limited in this regard. As long as the at least one third electrode 31 is electrically connected to the at least one second electrode 21b, the voltage drop problem of at least one light emitting device 21 (such as an OLED device) may be improved.

FIGS. 2A-2B are different schematic top views of a plurality of third electrodes in a display panel according to embodiments of the present disclosure. The plurality of third electrodes 31 may be in a strip shape as shown in FIG. 2A, or the plurality of third electrodes 31 may be in a block shape as shown in FIG. 2B. Here, the cross-sectional direction of FIG. 1 is the AA direction in FIG. 2A.

Here, since the third electrodes 31 are both auxiliary electrodes of the light-emitting device 21 and touch electrodes, the light-emitting device 21 can normally illuminate and the touch structure layer 30 can realize normal touch operation without affecting each other by adjusting the timing of the two different signals of the light-emitting and the touch, etc.

Based on this, by using the above-described display panel 01 provided by the embodiment of the present disclosure, when the third electrode 31 in the touch structure layer 30 is electrically connected to the second electrode 21b located at an upper portion of the light-emitting device 21, the equivalent resistance of the second electrode 21b may be reduced, and voltage drop problem of the light-emitting device 21 may be improved. At the same time, the third electrode 31 as the auxiliary electrode can also function as a touch structure in the touch structure layer 30, thereby realizing the effect of integration of the auxiliary electrode and the touch electrode, so that the display panel 01 having the In-cell Touch type (i.e., the touch module is inside the display panel) may be made ultra-thinner.

In addition, when the thickness of the second electrode 21b is relatively thin, the third electrode 31 electrically connected thereto may also serve to protect the second electrode 21b.

For example, the third electrode 31 may be made from at least one selected from the group of graphene, indium tin oxide (ITO), indium zinc oxide (IZO), or fluorine-doped tin oxide (FTO).

These materials have relatively good conductivity and are suitable to be electrode materials. Besides, the above-described materials are dense in structure, have good packaging characteristics, which may improve the protection and packaging of the underlying light-emitting device 21, and may integrate three functions of auxiliary cathodes, touches and packages.

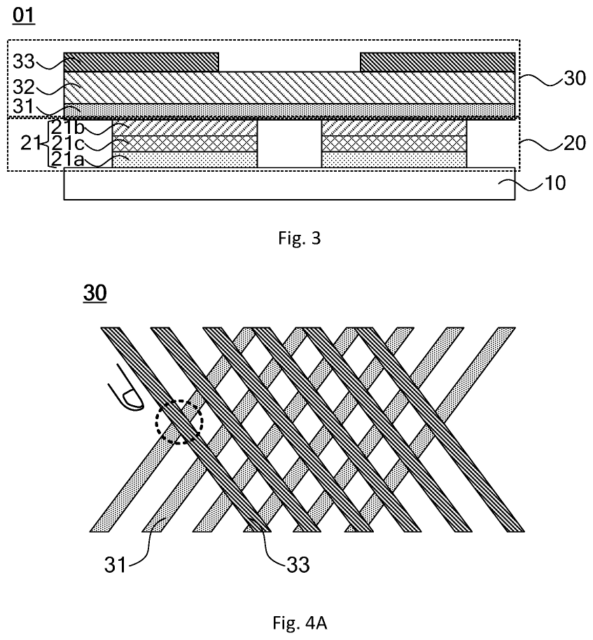

FIG. 3 is a schematic cross-sectional view of another display panel according to an embodiment of the present disclosure. For example, as shown in FIG. 3, the above-described touch structure layer 30 may further comprise: a first insulating layer 32 on a side of the plurality of third electrodes 31 away from the substrate.

In this way, the packaging of the underlying light emitting device 21 may be realized by the first insulating layer 32, and the structure of the thin film package layer and the like in the related art may be omitted, thus the thickness of the panel may be further reduced. Meanwhile, the first insulating layer 32 may also serve as a light scattering layer for the light emitting device layer 20, such that the light emitted by the light emitting device layer 20 is more efficiently distributed in a plane parallel to the substrate 10.

The first insulating layer may be made from at least one selected from the group of polytetrafluoroethylene (PTFE), fluoro polyethylene (PDFE), and polyimide (PI), and these materials are all low dielectric materials. The touch signals integrated in the display panel are easily affected by the display signals, and the problem may be improved by using a low dielectric material to electrically isolate the touch layer from the display layer.

For example, as shown in FIG. 3, the above-described touch structure layer 30 may further comprise a plurality of fourth electrodes 33 on a side of the first insulating layer (which may serve as a planarization layer) 32 away from the plurality of third electrodes 31. In some embodiments, a plurality of third electrodes 31 are spaced apart, a plurality of fourth electrodes 33 are spaced apart, and an orthographic projection of the third electrode 31 on the substrate 10 intersects with an orthographic projection of the fourth electrode 33 on the substrate 10. One of the third electrode 31 and the fourth electrode 33 is a touch driving electrode (Tx) and the other is a corresponding touch sensing electrode (Rx).

In this way, when the finger touches the surface of the display area of the display panel 01, the capacitance at the intersection of the third electrode 31 and the fourth electrode 33 may be changed, thereby performing touch recognition. The specific principle of the touch may be referred to the related art, which will not be described herein particularly by the embodiments of the present disclosure.

It should be noted that, FIG. 3 only schematically shows the outline where the third electrode 31 and the fourth electrode 33 are intersected with each other, and the number of the fourth electrodes 33 is merely illustrative and is not specifically limited.

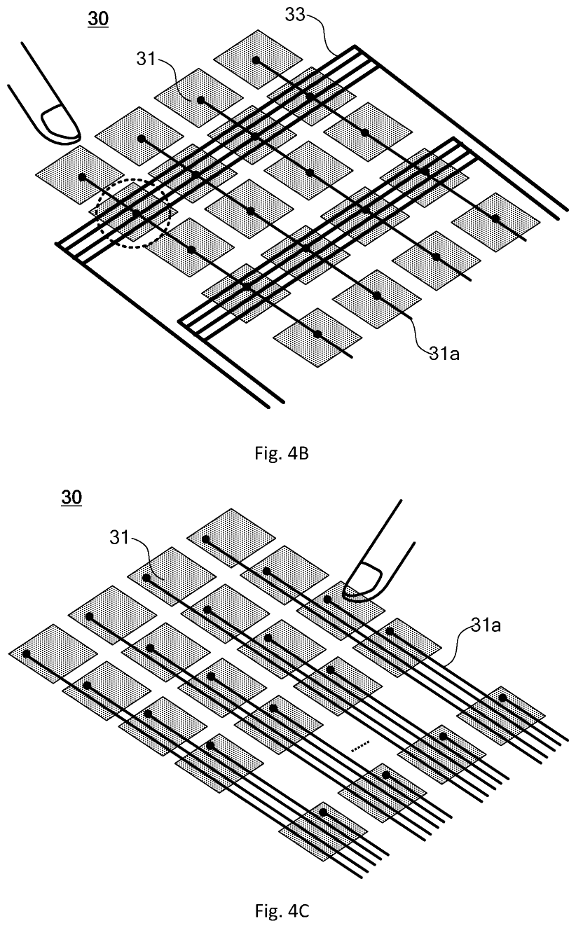

Here, for example, the third electrode 31 and the fourth electrode 33 may both be strip electrodes, and the intersection arrangement between them may be as shown in FIG. 4A. When a finger touches the area where the two electrodes are intersected (as shown by the dashed box in FIG. 4A, the first insulating layer between them is not shown), the mutual capacitance between the two electrodes may be changed, thereby performing touch recognition.

Alternatively, for example, the third electrode 31 may be a block electrode, and the fourth electrode 33 is a strip electrode intersecting therewith, and the intersection arrangement between the two electrodes may be as shown in FIG. 4B. When a finger touches the area where the two electrodes are intersected (as shown by the dashed box in FIG. 4B, the first insulating layer between them is not shown), the mutual capacitance between the two electrodes may be changed, thereby performing touch recognition. Wherein, one column or one row of third electrodes 31 are connected to one electrode line 31a to transmit corresponding electrical signals.

Of course, the touch structure layer 30 provided by the embodiment of the present disclosure is also applicable to the case of a single-layer touch electrode. As shown in FIG. 4C, the third electrode 31 is an electrode block, and each of the third electrodes 31 is independently connected onto one electrode line 31a. Since a transparent cover plate or the like is also required on the side of the third electrode 31 away from the substrate, the finger may not directly touch the conductive structure. Therefore, when the finger touches the surface of the display area of the display panel, self-capacitance of third electrode 31 which is overlapped with the touch position of the finger may be changed, thereby performing touch recognition.

It should be noted that, FIG. 4A to FIG. 4C are only possible implementations for illustrating several types of touch structure layers 30, and embodiments of the present disclosure are not limited thereto.

For example, in the above embodiment, the fourth electrode 33 may be made from a graphene electrode material or a nano-silver-doped graphene electrode material, and these materials also have relatively good conductivity and packaging characteristics, which contributes to further improve the packaging effect of the underlying light emitting device 21.

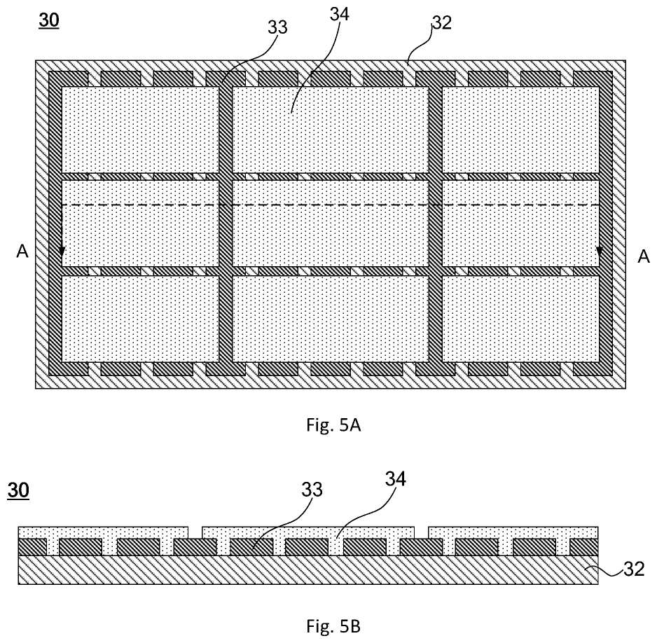

FIG. 5A is a partial schematic top view of a display panel according to an embodiment of the present disclosure; and FIG. 5B is a schematic cross-sectional view taken along line AA of FIG. 5A. For example, as shown in FIG. 5A and FIG. 5B, the above-described touch structure layer 30 may further comprise: a plurality of second insulating blocks 34 on a side of the first insulating layer 32 away from the plurality of third electrodes; wherein at least one fourth electrode 33 is provided between each second insulating block 34 and the first insulating layer 32.

Here, the underlying first inner insulating layer 32 disposed in entire layer may be used for packaging, and the individual second insulating blocks 34 may facilitate partition of the plurality of fourth electrodes 33, that is, an area where one second insulating block 34 is located may serve as one touch detection area to facilitate touch partition control.

Here, the above-described independent second insulating block 34 can also be made from at least one selected from the group of polytetrafluoroethylene (PTFE), fluoro polyethylene (PDFE), and polyimide (PI), and these materials are all low dielectric materials.

Moreover, in the related art, when a corresponding electrode pattern is fabricated on some organic low dielectric materials (for example, a dielectric constant is about 3.0˜5.0), the organic low dielectric material may not satisfy high temperature process requirements for fabricating the electrodes. Considering this, in the above-described display panel 01 provided by the embodiment of the present disclosure, a plurality of fourth electrodes 33 may therefore be formed by using an inkjet printing technique. The film drying temperature in the inkjet printing process is relatively low, and has less impact on the underlying first insulating layer 32.

A specific example is provided below for describing the above described display panel 01 in detail.

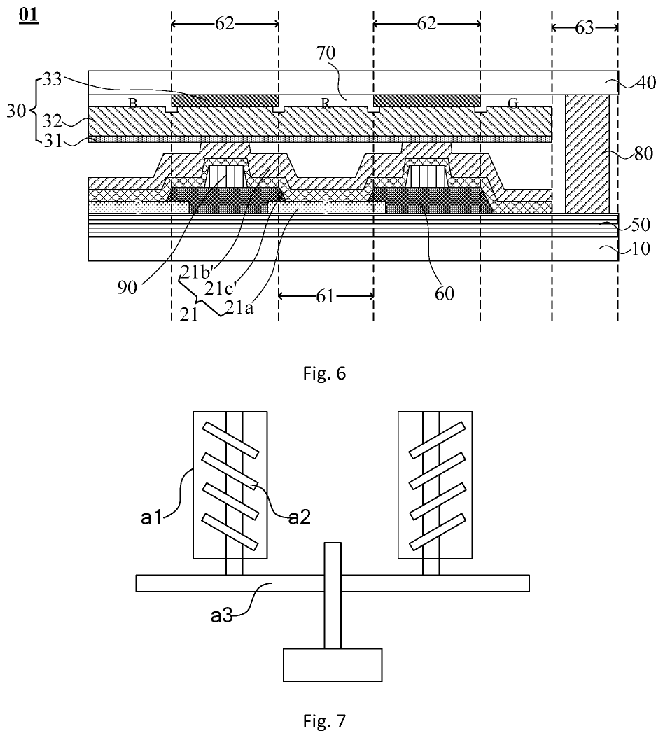

FIG. 6 is a schematic cross-sectional view of yet another display panel according to an embodiment of the present disclosure. As shown in FIG. 6, each of the second electrodes 21b of respective light-emitting devices 21 is connected together to form an entire layer of electrode 21b′, and each third electrode 31 of the plurality of third electrodes 31 is electrically connected to the entire layer of electrode 21b′.

Here, since each second electrode 21b in respective light-emitting devices 21 is generally a cathode, and the cathode generally receives a constant potential (for example, +5 V or +5 V), each second electrode 21b in respective light-emitting devices 21 is connected together to form the entire layer of electrode 21b′ to facilitate fabrication. Thus, it is not necessary to provide electrical signals to each of the second electrodes 21b separately, and the corresponding patterning process may also be omitted.

For example, the display panel 01 may further comprise: a transparent cover plate 40 on a side of the touch structure layer 30 away from the light emitting device layer 20; a thin film transistor array layer 50 between the substrate 10 and the light emitting device layer; a pixel defining layer (PDL) 60 on a side of the thin film transistor array layer 50 away from the substrate 10; wherein the pixel defining layer 60 is provided with openings 61, the respective one of which is corresponding to the first electrode 21a of each light emitting device 21, and the openings 61 are arranged in an array.

In some embodiments, the touch structure layer may further comprise a plurality of color filter blocks 70 between the adjacent two fourth electrodes 33 (for example, R, G, and B labeled in FIG. 6 respectively refer to a red filter block for filtering red light, a green filter block for filtering green light, and a blue filter block for filtering blue light). An orthographic projection of each of the plurality of color filter blocks 70 on the substrate 10 overlaps with the orthographic projection of the opening 61 on the substrate 10. In some embodiments, the light emitting functional portions 21c of each of the light emitting devices 21 are connected together to form an entire layer of white light emitting functional portion 21c′.

It is to be understood that, the above-described thin film transistor array layer 50 may generally comprise: a layer composed of a plurality of thin film transistors (TFT) arranged in an array, and an insulating layer (such as a planarization layer) disposed thereon. Vias are provided on these insulating layers, and the vias are corresponding to the drains (or sources) of the TFTs, so that the first electrode 21a of each of the light emitting devices 21 on the insulating layer may pass through the via to be electrically connected to the drain (or source) of the underlying TFT, to receive or transmit corresponding electrical signals. The specific structure may continue to use the related design, which will not be described herein particularly by the embodiments of the present disclosure.

Here, each of the openings 61 may correspond to at least a portion of the first electrode 21a of each of the light emitting devices 21, which means that when the pixel defining layer 60 is formed on the thin film transistor array layer 50 and other subsequent structures have not been formed yet, the opening 61 of the pixel defining layer 60 may expose at least a portion of the first electrode 21a (for example, to expose all of the first electrode 21a or only a portion of the first electrode 21).

The above-described light emitting device 21 may be exemplarily a white light-emitting WOLED device, which may be cooperated with the color filter block 70 to realize color display. Since each of the light emitting devices 21 emits white light, in some embodiments, the light emitting functional portions 21c of each of the light emitting devices 21 are connected together to form an entire layer of white light emitting functional portion 21c′ to simplify the fabricating process.

The entire layer of white light emitting functional portion 21c′ may further comprise a plurality of functional layers, which may comprise, for example, a hole transport layer (HTL), an electron transport layer (ETL), a hole injection layer (HIL), an electron injection layer (EIL), a white light emitting layer (EML, an example of which may be a lamination of a red-emitting layer, a green-emitting layer and a blue-emitting layer), and the electron blocking layer (EBL) and the like, which may be flexibly set according to the structural design requirements of the OLED device, and embodiments of the present disclosure are not limited in this regard.

Further, as shown in FIG. 6, since an orthographic projection of each of the plurality of color filter blocks 70 on the substrate 10 overlaps with the orthographic projection of the opening 61 on the substrate 10, the orthographic projection of the fourth electrode 33 between the color filter blocks 70 on the substrate 10 is in correspondence with the orthographic projection of the non-opening portion 62 of the PDL on the substrate 10. In some embodiments, the fourth electrode 33 is opaque or translucent, such that the fourth electrode 33 may serve as a black matrix structure in the related art (i.e., effectively shielding the exit light of the non-filter block area), thereby further simplifying the display panel structure. For example, when the fourth electrode 33 is an electrode made from graphene combined with nano-silver, the ratio of the nano-silver may be adjusted to adjust the degree of light transmission of the electrode.

In this way, the substrate 10, the thin film transistor array layer 50, the pixel defining layer 60, and the light emitting device layer 20 constitute a so-called OLED backplate (or OLED array substrate). Correspondingly, the transparent cover 40, the touch structure layer 30 and color filter block 70 constitutes a counter substrate (it is sometimes referred to as a touch color film substrate, since the substrate is integrated with touch and the color film functions) to be assembled with the OLED backplate (or OLED array substrate).

In the edge package area 63, a conductive sealant (for example, a silver-containing Dam adhesive) 80 for supporting the thin film transistor array layer 50 and the touch structure layer 30 and transmitting the corresponding signals thereon may be provided between the two substrates.

Further, as shown in FIG. 6, the above-described display panel 01 may further comprise: a plurality of post spacers (PS) 90 on a side of the pixel defining layer 60 away from the substrate 10. The entire layer of white light emitting functional portion 21c′ covers the pixel defining layer 60 and the post spacers 90. The entire layer of electrode 21b′ is located on a side of the entire layer of white light emitting functional portion 21c′ away from the substrate 10. The orthographic projection of the third electrode 31 on the substrate 10 overlaps with an orthographic projection of each of the post spacers 90 on the substrate 10.

In this way, the area of the light-emitting device 21 electrically connected to the third electrode 31 may be propped up by the post spacers 90, so that when the two substrates are assembled, the third electrode 31 is electrically connected to the entire layer of electrode 21b′. Meanwhile, in some embodiments, the post spacers 90 may serve as a dam for printing the light-emitting functional portion 21c to prevent overflow of the precursor ink of the light-emitting functional portion.

On the basis of the above, another exemplary embodiment of the present disclosure provides a method for fabricating a display panel, the method comprising the steps S01-S03:

Step S01, forming a light emitting device layer comprising a plurality of light emitting devices, wherein each of the plurality of light emitting devices comprises a first electrode, a light emitting functional portion, and a second electrode which are stacked in this order;

Step S02, forming a touch structure layer on a side of the light emitting device layer facing the second electrode, wherein the touch structure layer comprises a plurality of third electrodes; and

Step S03, assembling the light emitting device layer with the touch structure layer;

wherein at least one of the plurality of third electrodes is electrically connected to at least one second electrode.

For example, when the touch structure layer is fabricated on e.g. the transparent cover plate described above, the touch structure layer is fitted above the light emitting device layer after the touch structure layer is fabricated, to make at least one of the plurality of third electrodes of the touch structure layer electrically connect to the second electrode of the light emitting device layer.

In some embodiments, the above-described touch structure layer may also be directly formed on the light emitting device layer.

Further, referring to the related description of the foregoing display panel, the above-described step S02 of forming a touch structure layer may further comprise steps S021-S023:

Step S021, forming a first insulating layer;

Step S022, forming a third electrode on one side of the first insulating layer using by printing; and

Step S023, forming a fourth electrode on the other side of the first insulating layer by printing.

Here, since the drying temperature in the printing process is relatively low and the influence on the underlying substrate is relatively small, it is more suitable for the related preparation process in which the substrate comprises the low dielectric material.

In some embodiments, the printing process comprises an inkjet printing process.

In some embodiments, in the above-described touch structure layer, a critical dimension (CD) of the third and fourth electrodes and a pitch of the third and fourth electrodes (that is, the spacing between adjacent two third electrodes, and the spacing between adjacent two fourth electrodes) are both in the micron and submicron order, the third and the fourth electrodes intersecting with each other and being arranged in a mesh pattern. In this way, by making the electrodes have a smaller CD and pitch, more areas in which the third electrode and the fourth electrode intersect with each other are distributed in the display area of the entire display panel, and touch precision may be improved.

The related description of the inkjet printing process is as follows. The inkjet printing process requires a high concentration of graphene dispersion, and the viscosity (i.e., Z value) may be adjusted by selecting a suitable dispersion ratio between the solvent and graphene, to obtain a printing ink with a good ink drop ejection form. The inkjet printed graphene may be adapted to the related fabrication process of the transparent conductive electrode by controlling the printing parameters to optimize the patterning process of the inkjet printing.

The solvent of the graphene sheet liquid may be selected from highly volatile polar or non-polar organic solvents such as methanol, ethanol, propanol, butanol, acetone and the like. FIG. 7 shows the blending apparatus for blending the graphene sheet liquid and the solvent. The graphene sheets and the solvent are blended in the ultrasonic blending chamber with adding a protective carrier gas (e.g. an inert gas such as argon gas to prevent the graphene from being oxidized). After that, the mixture is rotated at a high speed and then transported to the rotating blending chamber a1, where the mixture is subjected to high-intensity ultrasonic vibration, so that the graphene sheet liquid and the solvent can be uniformly blended under the protection of the protective carrier gas.

The inner rotating rod a2 is provided in the rotating blending chamber a1, and the blending of the graphene sheets and the solvent may be driven by rotating the inner rotating rod a2. The rotating blending chamber a1 may also be disposed on the outer rotating rod a3, and the entire rotating blending chamber a1 may be driven to do a circular motion by rotating the outer rotating rod a3.

The structure for driving the inner rotating rod a2 and the outer rotating rod a3 to rotate may be, for example, a driving motor, and the specific structure may use the related devices, which will not be described herein particularly by the embodiments of the present disclosure.

After that, the blended ink is transported to the heating blending chamber through the transporting tube, and heating in the blending chamber increases the internal thermal kinetic energy of the gas-liquid solid suspension mixture. Then, the ink is transported to the piezoelectric ink ejection chamber, and the ink is ejected onto the corresponding substrate by high-speed ejecting. Then, the substrate is placed in the cooling device to perform a gas-solid separation of the residual protective carrier gas in the ink, so that the ink is deposited onto the substrate. Then, the substrate is post-baked, and the solvent in the ink is removed by volatilization, so that a corresponding graphene structure is formed on the surface of the substrate by the graphene. By precisely controlling the film formation parameters such as the ink concentration and the ejection amount, a film layer having a thickness of 10 nm or more may be formed.

The above inkjet printing process is merely illustrative, and embodiments of the present disclosure include, but are not limited to the above-described fabrication process, as long as the third electrode is fabricated and at least one of the plurality of third electrodes in the touch structure layer is electrically connected to the second electrode in the light emitting device layer.

Yet another exemplary embodiment of the present disclosure provides a display device comprising the display panel illustrated in the above embodiments.

The display device has the same advantages as the above-described display panel with respect to the related art, which will not be detailed herein.

Specifically, the above-described display device may be an OLED display device; the display device may be any product or component having a display function such as a television, a tablet, a mobile phone, a digital photo frame, a navigator, a wearable display device (such as a smart bracelet, a smart helmet, etc.), etc.

The above various display devices may further comprise components such as a driving circuit portion and a fingerprint identification structure. The specific structure can be found in the related art, which will not be described herein particularly by the embodiments of the present disclosure.

In the embodiments of the present disclosure, the third electrode in the touch structure layer is electrically connected to the second electrode located at an upper portion of the light emitting device, so that the voltage drop problem of the light emitting device may be improved. Meanwhile, the third electrode as the auxiliary electrode can also function as a corresponding touch structure in the touch structure layer (for example, a touch driving electrode (Tx) or a touch sensing electrode (Rx)), the first insulating layer in the touch structure layer may function as a light guide of the light emitting device layer, and the fourth electrode may function as a shielding layer of the light emitting device layer, thereby realizing the integration of the auxiliary electrode and the touch electrode. The above-described display panel having the In-cell Touch type (i.e., the touch module is inside the display panel) may be made ultra-thinner.

Many different ways of executing methods of embodiments of the present disclosure are possible, as will be apparent to a person skilled in the art. For example, the order of the steps can be varied or some steps may be executed in parallel. Moreover, in between steps other method steps may be inserted. The inserted steps may represent refinements of the method such as described herein, or may be unrelated to the method. Moreover, a given step may not have finished completely before a next step is started.

The above embodiments are only used for explanations rather than limitations to the present disclosure, the ordinary skilled person in the related technical field, in the case of not departing from the spirit and scope of the present disclosure, may also make various modifications and variations, therefore, all the equivalent solutions also belong to the scope of the present disclosure, the patent protection scope of the present disclosure should be defined by the claims.

1. A display panel comprising:
a light emitting device layer comprising a plurality of light emitting devices, wherein each of the plurality of light emitting devices comprises a first electrode, a light emitting functional portion and a second electrode which are stacked in this order; and
a touch structure layer on a side of the light emitting device layer facing the second electrode, wherein the touch structure layer comprises a plurality of third electrodes,
wherein at least one of the plurality of third electrodes is electrically connected to at least one second electrode.

2. The display panel according to claim 1, wherein the third electrodes are made from at least one selected from a group of graphene, indium tin oxide, indium zinc oxide, and fluorine-doped tin dioxide.

3. The display panel according to claim 1, wherein the touch structure layer further comprises a first insulating layer on a side of the plurality of third electrodes away from the light emitting device layer.

4. The display panel according to claim 3, wherein the first insulating layer is made from at least one selected from a group of polytetrafluoroethylene, fluoro polyethylene, and polyimide.

5. The display panel according to claim 3, wherein the touch structure layer further comprises a plurality of fourth electrodes on a side of the first insulating layer away from the plurality of third electrodes.

6. The display panel according to claim 5, wherein the fourth electrodes are opaque or translucent.

7. The display panel according to claim 5, wherein the fourth electrodes are made from a graphene electrode material or a nano-silver doped graphene electrode material.

8. The display panel according to claim 5, wherein the touch structure layer further comprises a plurality of second insulating blocks on a side of the first insulating layer away from the third electrodes, and at least one fourth electrode is provided between each of the plurality of the second insulating blocks and the first insulating layer.

9. The display panel according to claim 1, wherein second electrodes of the light emitting devices are connected together to form an entire layer of electrodes, and the third electrodes are electrically connected to the entire layer of electrodes.

10. The display panel according to claim 1, further comprising a substrate on a side of the light emitting device layer away from the touch structure layer.

11. The display panel according to claim 5, further comprising a transparent cover plate on a side of the touch structure layer away from the light emitting device layer.

12. The display panel according to claim 10, further comprising a pixel defining layer between the light emitting device layer and the substrate, wherein the pixel defining layer is provided with openings, a respective one of the openings is in correspondence with a respective one of the first electrodes, and the openings are arranged in an array.

13. The display panel according to claim 5, wherein the touch structure layer further comprises a plurality of color filter blocks between two adjacent fourth electrodes, and an orthographic projection of each of the plurality of color filter blocks on the substrate overlaps with an orthographic projection of each of a plurality of openings on the substrate.

14. The display panel according to claim 12, further comprising a plurality of post spacers on a side of the pixel defining layer away from the substrate.

15. The display panel according to claim 14, wherein light emitting functional portions of the light emitting devices are connected together to form an entire layer of light emitting functional portion, and the entire layer of light emitting functional portion covers the pixel defining layer and the post spacers.

16. The display panel according to claim 14, wherein an orthographic projection of each of the third electrodes on the substrate overlaps with an orthographic projection of each of the post spacers on the substrate.

17. The display panel according to claim 1, wherein light emitting functional portions of the light emitting devices emit light from a side facing the touch structure layer.

18. A display device, comprising the display panel of claim 1.

19. A method for fabricating a display panel, comprising:
forming a light emitting device layer comprising a plurality of light emitting devices, wherein each of the plurality of light emitting devices comprises a first electrode, a light emitting functional portion, and a second electrode which are stacked in this order;
forming a touch structure layer on a side of the light emitting device layer facing the second electrode, wherein the touch structure layer comprises a plurality of third electrodes; and
assembling the light emitting device layer with the touch structure layer,
wherein at least one of the plurality of third electrodes is electrically connected to at least one second electrode.

20. The method according to claim 19, wherein forming the touch structure layer comprises:
forming a first insulating layer;
forming the third electrodes on one side of the first insulating layer by printing; and
forming a fourth electrode on the other side of the first insulating layer by printing.
